(19) United States
(12) Patent Application Publication
(10) Pub. No.: US 2005/0048411 A1
(43) Pub. Date: Mar. 3, 2005

(54) Methods of patterning a monolayer

(76) Inventor: Graham John Leggett, Sheffield (GB)

Correspondence Address: CROWELL & MORING LLP;INTELLECTUAL PROPERTY GROUP, P.O. BOX 14300, WASHINGTON, DC, 20044-4300, US

(21) Appl. No.: 10/492,960

(22) PCT Filed: Oct. 21, 2002
(86) PCT No.: PCT/GB02/04751

(30) Foreign Application Priority Data
Oct. 19, 2001 (GB) 0125133.9

(51) Int. Cl. G03F 7/00

(52) U.S. Cl. 430/322; 430/396

(57) ABSTRACT

A method of patterning a monolayer including the steps of providing a monolayer of a compound on a substrate, positioning a near field light source in relation to the monolayer so that light from the light source irradiates the monolayer in the near field regime, the wavelength of the light being suitable to react with molecules in the monolayer and initiate a photochemical reaction, and patterning the monolayer by causing a relative movement of the monolayer and the near field light source, the relative movement corresponding to a desired pattern.

This invention relates to methods of patterning a monolayer, and to methods of selectively coupling a molecular species to such patterned monolayers.

In the past ten years there has been a great deal of scientific interest in the fabrication of micropatterned organic materials. This interest is driven by the potential utility of such materials in a wide range of technological applications. These include the development of hybrid organic-metallic or organic-semiconductor electronic devices (including, for example, molecular electronics and lab-on-a-chip technology) and the preparation of biological arrays. Array based systems are important tools for research in the biological sciences. The applications are wide-ranging, and include high-throughput DNA sequencing, biomolecular analysis and combinatorial testing methods. In many of these applications, high density arrays are utilised (for example, chips designed for DNA sequencing often incorporate thousands of individually addressable locations to each of which a distinct oligonucleotide sequence is attached). Demands for increasing analytical capability are creating pressure to generate ever more dense arrays, necessitating the attainment of decreasing feature sizes. An additional benefit of decreasing feature size is increased sensitivity. The ultimate sensitivity in biological analysis would be represented by the detection and analysis of single molecules. Array based methods offer the promise of ultra-high sensitive analysis, provided that methods are developed for creating adequately small features. There is consequently widespread interest in methods for the fabrication of biological structures and arrays with nanometre dimensions, although few successful methods currently exist. Outside of the biological sciences, there is much interest in the miniaturisation of electronic circuitry to facilitate the fabrication of microprocessors and information storage systems with greater capability. There is also much interest in the development of methods for the fabrication of miniaturised electronic devices from new materials, where greater ease of fabrication is possible, or where new materials (for example, organic materials) might be used in place of conventional ones. All of these technologies place a requirement for new methods for the fabrication of nanometre scale structures and for the control of molecular structure at the nanometre scale. Whilst a number of methods are available for creating micron-scale patterns, there are very few that are capable of being used to fabricate nanostructured materials (ie materials with feature sizes less than 100 nm).

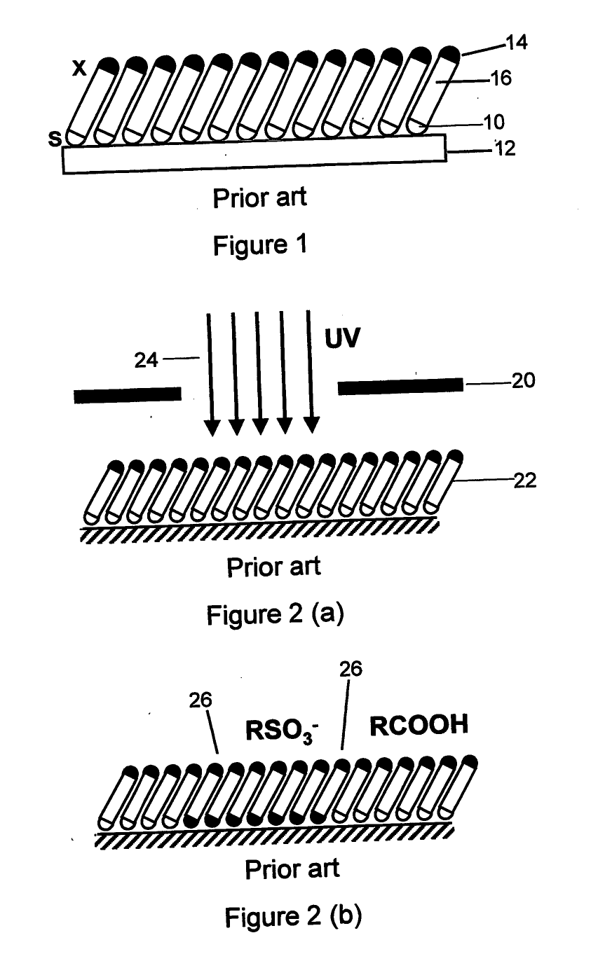

A variety of types of materials have been patterned, including polymers and organic monolayers. Self-assembled monolayers (SAMs) have emerged as potentially very useful materials in such applications. These materials are formed by the adsorption of alkanethiols HS(CH₂)ₙX onto gold, silver and some other surfaces. The thiol-on-gold SAM is the most widely studied system. The main components (see FIG. 1) are a thiol group 10, which tethers the adsorbate to a substrate such as gold through a strong specific interaction (effectively a covalent bond), a tail group X 14 which is directed away from the surface, and an alkyl chain 16 that links the two together. The properties of the surface may be controlled by changing the structure of the adsorbate molecule. For example, the wettability may be controlled by changing the tail group. Methyl terminated SAMs are very hydrophobic—water contact angles are in the range 99-115°, depending on the length of the alkyl chain—while SAMs with polar tail groups (eg OH, COOH) may be hydrophilic, with contact angles typically less than 15°.

The most widely used method for making patterned SAMs is microcontact printing (μCP). This simple, flexible method involves creating a silicon relief mask by photolithography, and casting silicone elastomer onto the mask. After curing, the silicone may be removed from the master and the relief features inked with a solution of a thiol, which may then be transferred to a gold substrate by stamping. This method is very easy to use and versatile. There is considerable interest in extending its capability to the nm scale. However, it is difficult to accurately create features with adequately well-defined dimensions at the nm scale. The best results obtained thus far have been by squeezing a stamp with micron scale features. The resulting compression results in features as small as 100 nm, but there are clear limitations in the types of features that may be created using the method.

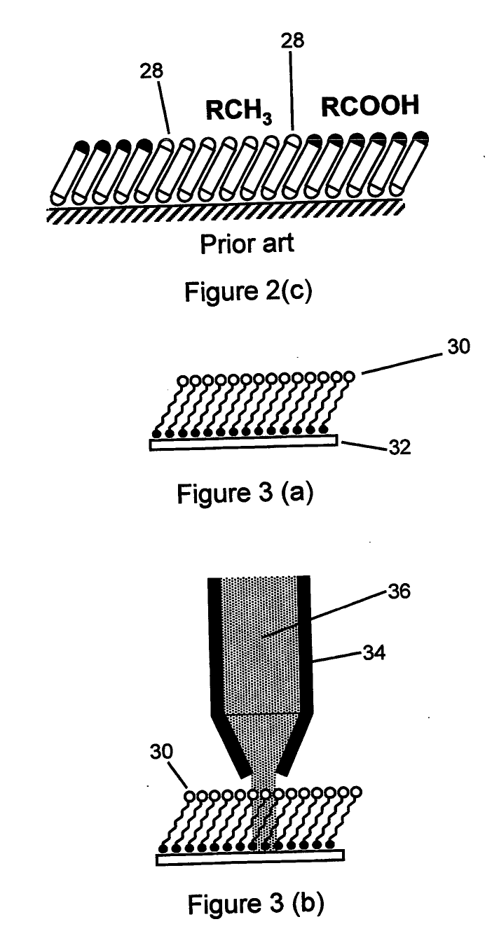

An alternative approach is disclosed in U.S. Pat. No. 5,514,501. This photolithographic procedure is depicted in FIG. 2, and involved placing a mask 20 over the surface of a thiol 22 of one particular chemistry (in FIG. 2, this is a carboxylic acid terminated thiol). The sample is then exposed to UV light 24 (FIG. 2(a)). In exposed areas, the thiols are converted to alkylsulphonates, RSO₃26 (FIG. 2(b)). While the thiols are bound strongly to the underlying gold, the sulphonates are only weakly bound. The sample is then dipped into a solution of a second thiol, displacing the sulphonates and adsorbing the second thiol 28 at the surface (FIG. 2(c)). If this second thiol 28 has a different tail group chemistry (eg, methyl as shown in FIG. 2), the result will be a chemical pattern, in which the masked areas contain the original chemistry and the exposed areas contain a new chemistry. This method is very effective and easy to use. The resulting patterns have clean, well-defined chemical structures and good edge-definition. The drawback is that it relies upon exposure through a mask, which imposes a limitation on feature sizes: conventional photolithography using UV light is not capable of creating nanostructures because diffraction occurs when the features in the mask become smaller than half the wavelength of the light used.

Nanoscale patterned SAMs have been produced using a technique known as dip-pen nanolithography (DPN). This method, which is not a photolithographic method, involves dipping the tip of an atomic force microscope in a solution of an alkane thiol, and then using the tip to transfer the thiol to a gold surface much as a pen would write with ink on a sheet of paper. DPN as been successfully used to create features with dimensions of a few tens of nanometres.

Scanning near field optical microscopes (SNOMs) have been in usage since the early 1990s. In a SNOM, a narrow optical fibre (having an internal diameter as small as 50 nm) is brought in close proximity to a sample surface. Under such conditions, as a result of a near field effect, light may be transmitted through the aperture without undergoing diffraction, even though the fibre aperture is smaller than half the wavelength of the light. SNOMs have been used principally as optical probes for surface characterisation. Some attempts have been made to use SNOMs in order to perform very high resolution photolithography. In particular, attempts have been made to pattern conventional photo-resist materials using a SNOM. However, disappointing results have been obtained, and it is believed that the reason for this lack of success is that either light from the SNOM tends to diverge within the resist layer and/or that thermal transfer (ie, heating) is occurring, with the consequence that the feature sizes have generally been larger than 100 nm. A small number of investigations have reported feature sizes slightly smaller than 100 nm, but the features have rarely been sharply defined. International Publication WO98/58293 discloses a number of techniques for immobilising macromolecules on a surface, one of which is initiated by the use of optical near field microscopy to photoactivate functional groups on a layer which is disposed on a surface. The technique appears to be rather speculative in nature: no experimental details are provided (such as the depth of the layer), and no quantitative indication is provided of the feature size which may be produced. The general leaning in the art is that SNOM techniques are unsuitable for high resolution nonstructural patterning.

The present invention overcomes the above mentioned problems, limitations and disadvantages, and provides a photolithographic method which can enable high resolution patterning of substrates on a scale of a few tens of nanometres.

According to a first aspect of the invention there is provided a method of patterning a monolayer of a compound comprising steps of:
providing a monolayer on a substrate;
positioning a near field light source in relation to the monolayer so that light from the light source irradiates the monolayer in the near field regime, the wavelength of the light being suitable to interact with molecules in the monolayer and thereby initiate a photochemical reaction; and
patterning the monolayer by causing relative movement of the monolayer and the near field light source, the relative movement corresponding to a desired pattern.

In this way it is possible to fabricate structures having well defined chemistries and dimensions. A wide range of feature sizes can be produced, including nanostructures. Feature sizes in the range of a few tens of nanometres are possible. Surprisingly, it has been found that near field techniques can be used to produce such well defined features, despite the relatively poor spatial resolution achieved with prior art techniques which utilised a SNOM to pattern photoresists. It is believed that the improvement afforded by the present invention is, at least in part, due to the provision of a monolayer on the substrate. It is believed that light from the near field light source does not diverge through the monolayer and/or cause local heating effects, in contrast to the conventional photoresists utilised in the prior art.

The monolayer may be a SAM, such as a thiolate SAM, or monolayers of alkylsilanes, carboxylic acids or phosphonic acids. Langmuir-Blodgett films are possible alternatives.

Preferably, the near field light source comprises a scanning near field microscope (SNOM). It should be noted that some manufacturers term such instruments near field scanning optical microscopes (NSOMs), and that for the avoidance of doubt, such terms should be regarded as being equivalent to SNOM. The use of other forms of near field light sources is within the scope of the invention.

The molecules in the monolayer which absorb light from the light source may be converted by the photochemical reaction into a weakly bound species which is less strongly bound to the substrate than the molecules which originally comprise the monolayer. The method may further comprise the step of displacing the weakly bound species from the substrate with a displacing species. The displacing species may comprise a component of a chemical etch. The chemical etch may etch the substrate.

The photochemical reaction may be a photooxidation reaction. The photooxidation reaction may be used to convert molecules in the SAM into a weakly bound species in the manner described above. In such instances, it is likely that a ‘head’ group, in contact with the substrate, will be oxidised. However, other oxidative processes, such as photooxidation of one ‘end’ group or of an alkyl chain, are possible. Alternatively, a different type of photochemical reaction may be initiated. Photoactivation of a group may be performed, for example to attach molecules (such as biological molecules) to an end group, or to initiate cross linking of groups such as diacetylenic groups. In the latter instance, the position of the diacetylenic groups may be the subject of variation; generally they are about half way along an alkyl chain. The photochemical reaction might comprise a unimolecular reaction or even a half-reaction. Furthermore, desorption or ablation may occur, either as a main patterning mechanism or in conjunction with a photochemical reaction, and such processes should be considered to be a photochemical reaction for the purpose of the present invention.

The molecules in the SAM may comprise thiolates. The SAM may be formed from thiols, which may comprise alkylthiols. The thiols may be of the formula HS(CH₂)ₙX where X is an end group. The end group X may be any functional group which provides desired characteristics, eg. reactivity, hydrophobicity, etc. The end group X may be selected from the group consisting of CH₃, CO₂H and OH. Typically n is in the range 0 to 20. Other possibilities are within the scope of the invention. For example, the thiolate may be partially or per fluorinated, and other end groups, such as NH₂, CF₃, halogen, etc, may be used. Other compounds capable of providing thiolate SAMs, such as dialkyl sulphides and dialkyl disulphides, might be used in place of thiols.

In the instance in which the molecules in the SAM comprise thiolates, and the photochemical reaction is a photooxidation reaction, the photooxidation reaction may oxidise thiolate moieties adsorbed on the substrate to sulphonate moieties. The sulphates produced by such a photooxidation are relatively weakly bound to the substrate. The sulphonates (or any other weakly bound species) may be displaced from the substrate with a displacing species which forms a thiolate compound on the substrate. Thiols, dialkyl sulphides and dialkyl disulphides are candidates as displacing species. It should be noted that there is controversy in the literature over the mechanism of the photooxidation to sulphonates. Many studies suggest the primary mechanism is ozonolysis, a mechanism which would be inconsistent with the mechanism of the present invention, in which close positioning of SNOM and SAM are effected in order to achieve near field conditions and direct interaction of light from the SNOM with the SAM.

The substrate may comprise gold or silver. Other candidates include copper, platinum, iridium, palladium, rhodium, mercury, osmium, ruthenium, and semiconducting materials such as gallium arsenide, iridium phosphide, mercury cadmium telluride and silicon.

The light source may provide near UV light. For example, in order to oxidise thiolate moieties to sulphonate moieties, wavelengths of around 240 to 260 nm are desirable. The skilled reader will appreciate that the optimal wavelength or wavelength range will depend on numerous features such as the wavelength dependence of both the absorption coefficients of the molecular species in question and the quantum yield for the desired photochemical reaction, and the nature and availability of possible light sources (typically laser light sources). Other regions of the electromagnetic spectrum might be used, depending on the photochemical scheme employed. For example, vacuum UV light might be used to pattern silane monolayers, such as the 193 nm output of an ArF excimer laser.

The patterning may comprise features having at least one dimension in a direction parallel to the substrate which is less than 100 nm, preferably less than 50 nm.

According to a second aspect of the invention there is provided a method of selectively coupling a molecular species to a surface, comprising the steps of:
pattering a monolayer using a method in accordance with the first aspect of the invention to provide one or more features; and
coupling the molecular species to a compound present on the substrate.

In this way it is possible to produce a vast range of devices having structures which exhibit a desired functionality, in which the dimensions associated with such structures are of the order of tens of nanometres.

The molecular species may be coupled to the monolayer, ie, the coupling may be to the monolayer itself, rather than to the regions which have been patterned.

Alternatively, the molecular species may be coupled to the features. For example, in the instance in which a displacing species has displaced a weakly bound species from the substrate in the patterned region corresponding to the features, the molecular species may be coupled to the displacing species.

Alternatively still, an intermediate compound or compounds may be coupled to a portion of the patterned monolayer (which may be the monolayer or the features), and the molecular species coupled to the intermediate compound.

The coupling may comprise adsorption of the molecular species onto the compound. Such coupling schemes are disclosed in U.S. Pat. No. 5,514,501, the contents of which are incorporated by reference.

The coupling may comprise covalently bonding the molecular species to the compound. Many such coupling schemes are known in the literature: for example, P. Wagner, P. Kerned, M. Hegner, E. Ungewickell and G. Semenza, FEBS letters 356 (1994); N. Patel, M. C. Davies, M. Hartshorne, R. J. Heaton, C. J.Roberts, S. J. B. Tendler and P. M. Williams, Langmuir 13 (1997) 6485-6490; G. J. Leggett, C. J. Roberts, P. M. Williams, M. C. Davies, D. E. Jackson and S. J. B. Tendler, Langmuir 9 (1993), 2356-2362; and G. J. Leggett, C. J. Roberts, P. M. Williams, M. C. Davies, D. E. Jackson and S. J. B. Tendler, Langmuir, 9 (1993), 2356-2362, and W. Knoll, L. Angermaier, G. Batz, T. Fritz, S. Fujisawa, T. Furano, H. J. Guder, M, Hara, M. Liley, K. Niki and J. Spinke, Synth. Met 61 (1993) 5, the contents of which are hereby incorporated by reference. Thus, for example, water soluble carbodimides either with or without the use of N-hydroxysuccinimide can be used to attach proteins to carboxylic acid terminated SAMs, and photopatterned SAMs can be derivatised with perfluorinated molecules (see, for example, D. A. Hutt and G. J. Leggett, Langmuir, 13 (1997) 2740-2748) the contents of which are hereby incorporated by reference). Thiols terminated in biotin can be absorbed onto the substrate—perhaps being used as the displacing species. The biotin terminated thiols can be used to bind streptavidin molecules, which then bind biotinylated antibodies.

The molecular species may be a biological molecule. The biological molecule may be a protein, a DNA strand, an RNA strand, an oligonucleotide or an enzyme. In this way, devices to perform operations such as biosensing, sequencing, synthesis and chemical or biological analysis can be fabricated comprising, if necessary, nanostructures.

Embodiments of methods in accordance with the invention will now be described with reference to the accompanying drawings, in which:

FIG. 1 shows a self assembled monolayer (SAM);

FIG. 2 shows a prior art patterning technique;

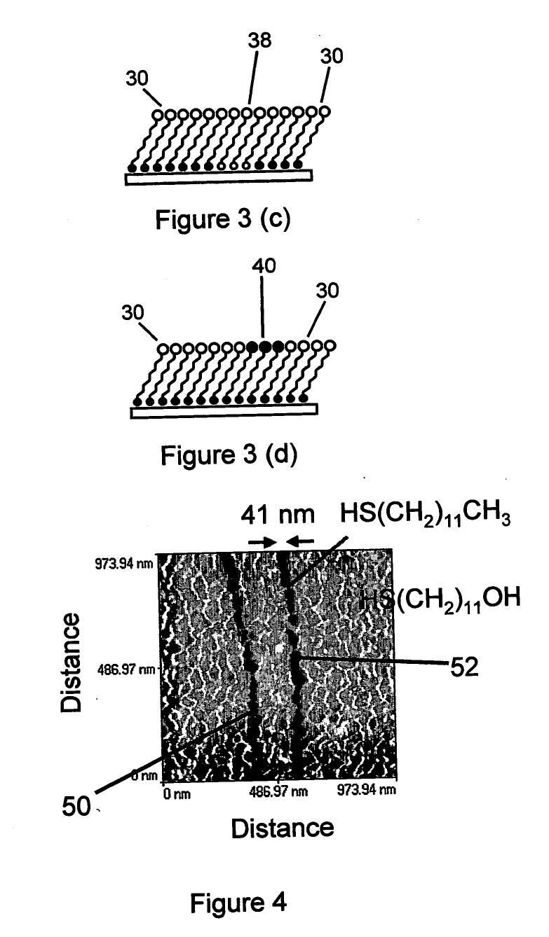

FIG. 3 shows a) the formation of a SAM on a substrate, b) treatment of the SAM with a SNOM, c) photooxidised regions of the SAM, and d), the displacement of oxidised molecules by a displacing species; and

FIG. 4 shows a lateral force microscopy image of a patterned hydroxyl terminated SAM; and

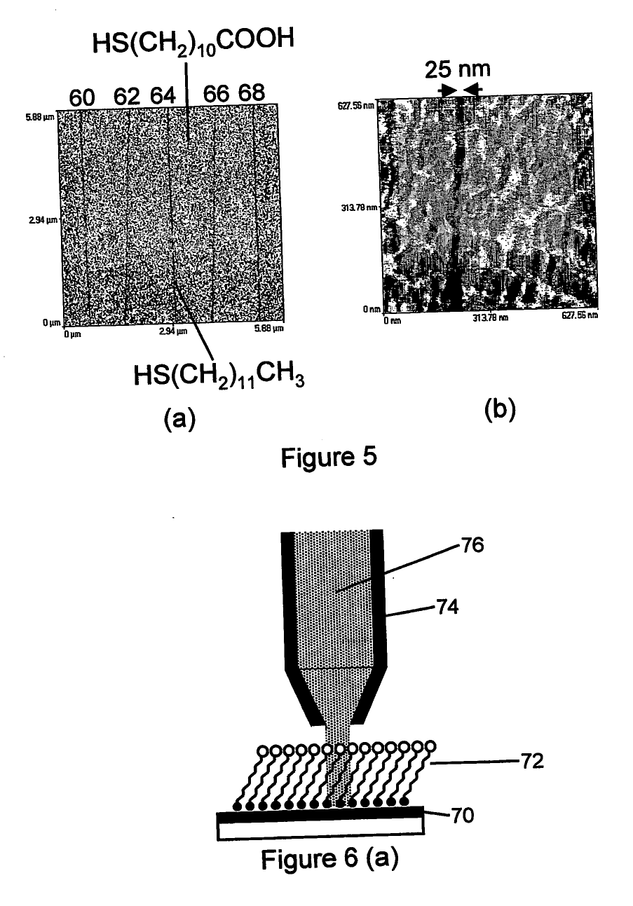

FIG. 5 shows (a) a lateral force microscopy image of a patterned carboxylic acid terminated SAM and (b) a close view of a line present in (a);

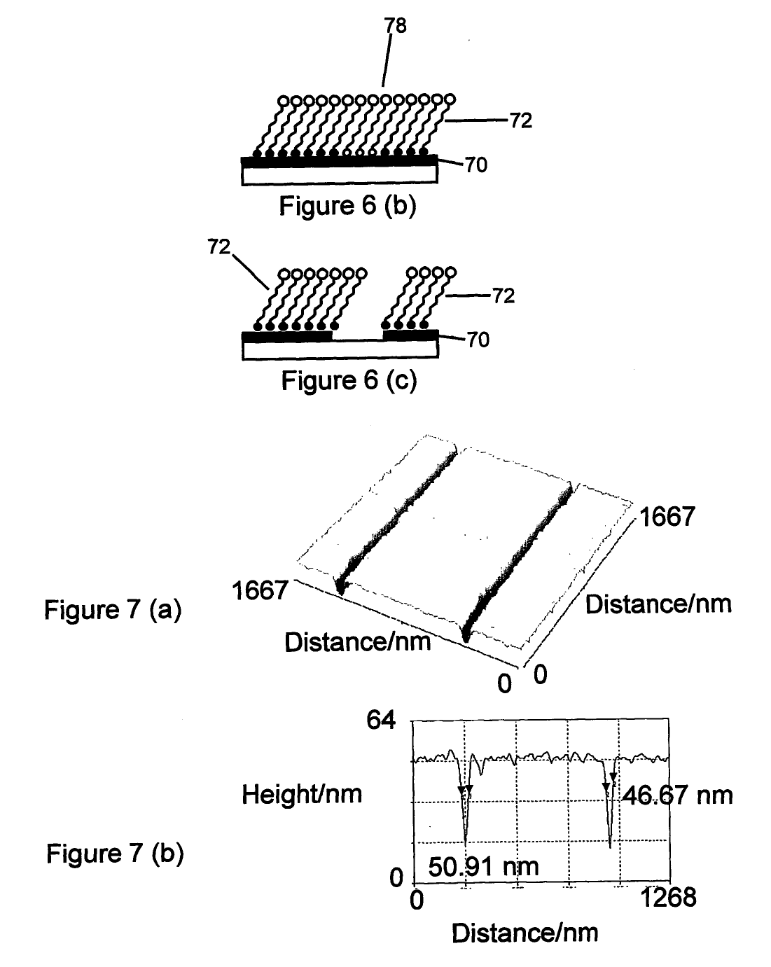

FIG. 6 shows (a) treatment of a SAM on a gold surface with a SNOM, (b) photooxidised regions of the SAM, and (c ) etching of the gold surface; and

FIG. 7 shows (a) an atomic force microscopy image of an etched SAM/gold surface and (b) a cross sectional view through the image of (a).

FIG. 3 depicts a method of patterning a SAM in accordance with the invention. In step (a) a SAM 30 is formed on a suitable substrate 32. In step (b), a SNOM is disposed very close to the SAM 30 so that interaction in the near field regime can occur. The SNOM tip 34 is shown in FIG. 3(b), the tip 34 typically comprising a narrow optical fibre (eg, of internal diameter ca. 50 nm). The SNOM irradiates the SAM 30 with light 36 of an appropriate wavelength to initiate a desired photochemistry. Under near field conditions, the light 36 passes through the aperture formed by the end of the optical fibre 34 without undergoing diffraction, even though the diameter of the aperture may be less than half of the wavelength of the light. The SNOM is moved in relation to the SAM 30 in order to effect the desired pattern on the SAM 30. FIG. 3(c) shows the result of the irradiation of the SAM 30 with light 36 from the SNOM: highly localised conversion occurs of the molecules in the SAM 30 into a more weakly bound species 38. Wherever the SNOM fibre has travelled, the SAM 30 is converted into the more weakly bound species 38. Next the SAM 30 is treated with a displacing species, such as by immersion in a solution of the displacing species. As shown in FIG. 3(d) the displacing species 40 displaces the weakly bound species 38 from the substrate, and adsorbs at the surface of the substrate 32, resulting in a patterned SAM with a precisely defined chemical structure. The patterning is defined by relative ratios of the SNOM aperture and the SAM, and may be of a dimension commensurate with the near field regime employed. Patterning dimensions as small as 40 nm can be routinely achieved, and dimensions as small as 25 nm have been produced. It should be noted that patterned structures of larger dimensions, for example over 1 μm, can be produced using the method of the present invention should this be desired.

There are many possible variations upon the scheme depicted in FIG. 3 which are within the scope of the invention. For example, alkyl thiols or thiophenols may be used to form the SAM. Other types of compounds still which, nevertheless, form a thiolate SAM on the substrate may be used. Such compounds include dialkyl disulphides, which are of the general formula R(CH₂)ₘS—S(CH₂)ₙR′ where R and R′ are terminal functional groups and m and n are each typically in the range 0 to 20. Other candidates include dialkyl sulphides, which are of the general formula R(CH₂)ₘS(CH₂)ₙR′ where R and R′ are terminal functional groups(and may be identical), and m and n are each typically in the range 0 to 20. All of these species are candidates for use as the displacing species as well.

Although thiolate SAMs represent presently preferred embodiments of the present invention, it is possible to utilise other types of SAMs. For example, silane compounds might be used, eg, an alkyl silane on a silicon surface. In this instance, a possible choice of system and photochemistry could comprise diacetylenic silanes, the diacetylenic moieties being cross linked via photoinitiation with light from the SNOM.

It is known that monolayers of alkylsilanes on silicon can be patterned using photolithographic methods (S. L. Brandow, M.-S. Chen, R. Aggarwal, C. S. Dulcey, J. M. Calvert and J. Dressick, Langmuir 15 (1999) 5429; S. L. Brandow, M.-S.Chen, S. J. Fertig, L. A. Chrisey, C. S. Dulcey and W. J. Dressick, Chem. Eur.J. 7 (2001) 4495; W. J. Dressick, M.-S. Chen and S. L. Brandow, J.Am. Chem. Soc. 122 (2000) 982, the contents of which are herein incorporated by reference). In these investigations, a monolayer of chloromethylphenylsilane is formed, and then exposed to UV light through a mask. Chloromethylphenysilanes absorb strongly at around 193 nm and weakly at around 254 nm. Exposure to 193 nm light causes photooxidation of the chloromethyl group, converting it to an aldehyde functionality. This aldehyde functionality may be used as the site of attachment of either organic molecules or metals. In place of the mask utilised in this prior art technique, it is possible to use excitation with a near field light source, such as a SNOM, at around 193 nm or 254 nm in order to initiate photochemistry and thereby pattern a silane SAM on a silicon surface.

Other possibilities include monolayers of carboxylic acids on, for example, alumina surfaces, and monolayers of phosphonic acids on, for example, indium tin oxide surfaces. It may be possible to utilise Langmuir-Blodgett monolayer films instead of SAMs.

It is possible to utilise other photochemical reactions instead of the photooxidation scheme depicted in FIG. 3. Diacetylenic moieties present in the monolayer may be cross linked using the SNOM to form extended conjugated structures. Cross linking procedures are discussed in D. N. Batchelor, S. D. Evans, T. L. Freeman, H. Ringsdorf and H. Wolf, J.Am. Chem.Soc 116 (1994) 1050-1053, and M.Cai, D. Mowery. H. Menzel and C. E. Evans, Langmuir 15 (1999) 1215-1222, the contents of which are herein incorporated by reference. In this way, nanoscale organic circuits might be produced by attaching a monolayer of a suitable diacetylenic containing compound to a substrate and using a SNOM to trace patterns corresponding to the described circuitry on the monolayer. Along this pattern, the diacetylenic groups cross-link to form conjugated, conducting molecular wires. Diacetylenic silanes may be utilised, and the monolayer may be formed on a silicone oxide surface. Other photochemical reactions might include the photocleaving of protecting groups which exposes functionalities that are reactive with respect to solution phase metallic species.

Another alternative photochemical scheme involves the use of a monolayer comprising molecules having photoactive end groups to which biological molecules may be attached after photoactivation using light from the SNOM. Examples of such photochemical schemes can be found in E. Delamarche, G. Sundarababu, H. Biebuyck, Ch. Gerbert, H. Sigrist, H. Wolf, H. Ringsdorf, N. Xanthopoulos and H. J. Mathieu, Langmuir 12 (1996) 1997-2006, and Z. Yang,W. Frey, T. Oliver and A. Chilkoti, Langmuir 16 (2000) 1751, and A. S. Blawas and W. M. Reichert, Biomaterials 19 (1998) 595, the contents of which are hereby incorporated by reference.

### EXAMPLE 1

Self-assembled monolayers were prepared by immersing freshly deposited layers of gold (30 nm) on chromium (20 nm) primed glass microscope slides in 1 mMol dm⁻³ solutions of alkanethiols in ethanol. The lithography experiments were carried out using a ThermoMicroscopes Aurora Near-field Scanning Optical Microscope. Fused silica optical probes were specially manufactured by ThermoMicroscopes and coupled to a fused silica fibre. The nominal internal diameter of the probes was 50 nm. The optical fibre was coupled to a Coherent Innova 300C FreD frequency-doubled argon ion laser. The fundamental wavelength at 488 nm was doubled using a beta barium borate (BBO) crystal cut at the Brewster angle. Features were creating by tracing the optical probe across the sample surface in a pattern controlled by the lithography software of the SNOM and subsequently immersing the sample in a 10 mMol dm⁻³ solution of an alkyl thiol with a contrasting terminal group functionality. The resulting nanometre scale patterns were imaged using a ThermoMicroscopes Explorer Atomic Force Microscope in Lateral Force Mode.

The wavelength of 244 nm is suitable to initiate photooxidation of thiolate species in the SAM to the relatively weakly bound sulphonate species. The sulphonate species are displaced by the alkyl thiol.

An HS(CH₂)₁₁OH SAM was patterned in the above described manner. A solution of HS(CH₂)₁₁CH₃ was used to displace the sulphonate species produced after SNOM patterning. The resultant patterned SAM was imaged by lateral force microscopy, which is a variant of atomic force microscopy in which local variations in surface friction are measured. The image is shown in FIG. 4. Low contrast is observed in regions corresponding to the methyl terminated SAM, because these regions exhibit a relatively low coefficient of friction. Bright contrast is observed in regions corresponding to the hydroxyl terminated SAM, these regions exhibiting a higher coefficient of friction. Referring to FIG. 4, two lines 50, 52 of low contrast can be seen, corresponding to adsorbed HS(CH₂)₁₁CH₃. The width of the lines 50, 52 is ca. 40 nm.

### EXAMPLE 2

The method of Example 1 was utilised to pattern a SAM formed using HS(CH₂)₁₁CO₂H. A lateral force microscopy image of the patterned SAM is shown in FIG. 5. FIG. 5(a) shows a plurality of lines 60, 62, 64, 66, 68 of low contrast, corresponding to adsorbed HS(CH₂)₁₁CH₃, the lines 60, 62, 64, 66, 68 being visible on a background of bright contrast, corresponding to the carboxylic acid terminated SAM. FIG. 5(b) shows a close up view of one of the lines. The width of this line is only 25 nm.

### EXAMPLE 3

The method of Example 1 was utilised to pattern a SAM formed using HS(CH₂)₁₁CH₃. In this instance, both HS(CH₂)₁₁OH and HS(CH₂)₁₁CO₂H have been used successfully as the displacing species.

### EXAMPLE 4

The present invention was utilised in a process for patterning gold films. The process is depicted schematically in FIG. 6. A gold film 70 has a self-assembled monolayer (SAM) of an alkanethiol 72 formed thereon. A SNOM is disposed very close to the SAM 72 so that interaction in the near field regime can occur. The SNOM 74 is shown in FIG. 6(a), which irradiates the SAM 72 with light 76 of an appropriate wavelength to initiate photochemistry of the type described previously, ie, the photooxidation of the thiolate species to a relatively weakly bound sulphonate species 78. FIG. 6(b) depicts the patterned SAM 72, which now comprises areas of weakly bound sulphonates 78. Thereafter, the patterned SAM 72 and gold film 70 are subjected to a chemical etch. The chemical etch is sufficient to remove the sulphonate species 78 and etch gold underlying the sulphonate species. However, as shown in FIG. 6(c), the etch does not displace the alkanethol 72. Thus, the underlying gold film can be etched in a pattern defined by the SNOM. In a non-limiting example, a gold film was covered with a SAM of hexadecanethiol. The SAM was etched using a SNOM operating at 244 nm by way of tracing two lines in the SAM. The patterned SAM formed by this process was immersed in a ferri/ferrocyanide etch solution, which removed gold underlying the oxidised regions of the SAM, eg, the portions of the gold film underneath the two line pattern traced on the SAM. FIGS. 7(a) and 7(b) show an atomic force microscopy image of the resulting etched film Two trenches, corresponding to the two lines patterned by the SNOM, are clearly discernible. The width of the trenches is only 50 nm, which is equal to the diameter of the aperture in the SNOM tip 74. This example demonstrates that the SNOM technique of the present invention can be used in conjunction with wet etching to create metallic nanostructures whose dimensions are effectively limited by the diameter of the aperture in the probe used for patterning. The image shown in FIG. 7 is of the etched gold substrate with the patterned SAM thereon. If desired, it is straightforward to remove the SAM to leave the etched gold surface. Removal of the SAM can be achieved through exposure to UV light followed by washing.

It is known (Y. Xia, X-M. Zhao, E. Kim and G. M. Whitesides, Chem. Mater., 7 (1995) 2332, the contents of which are herein incorporated by reference) to apply thiols onto a metal surface using microcontact printing, and thereafter to expose the patterns thus formed to a wet etch. This process results in removal of metal from exposed regions (ie, regions not covered with thiols). An advantage of the present invention compared to microcontact printing is that it generates more stable patterns. Because the defect density in monolayers formed by microcontact is higher, they are more susceptible to attack by etchants for the gold film. In contract, the unoxidised regions of patterns form by the present invention are up to ten times more stable than corresponding masking regions formed by microcontact printing, a significant advantage in practical applications.

These data illustrate (i) that SNOM-patterned monolayers are very stable and (ii) that SNOM is capable of diverse applications (in other words, it is not limited to the patterning of surface chemical structures alone).

Subsequent Functionalisation of the Patterned SAM

Judicious selection of the end groups present on the patterned monolayer can enable the selective coupling of desired molecular species to the patterned monolayer. The molecular species might be coupled to the patterned areas of the monolayer (ie, the lines 50, 52 in FIG. 4), or to molecules of the monolayer itself (ie, the areas of bright contrast depicted in FIG. 4). In principle, different molecular species might be coupled to each area. In practise, a single molecular species will be coupled to one of these areas. The identity of the compound present in the other area where the molecular species is not intended to be present will be selected so that coupling does not occur. Combinations of the type described in Examples 1 to 3 above are useful, ie, a polar end group such as OH or CO₂H in combination with a hydrophobic end such as methyl. The molecular species might be coupled by adsorption of the molecular species onto a compound present on the substrate. For example, U.S. Pat. No. 5,514,501 describes various immobilisation procedures in which a number of biological molecules are adsorbed onto a SAM composed of carboxyl terminated thiolates. The other areas of the patterned SAMs may be composed of thiolates that do not adsorb the biological molecules to any great extent, for example hydroxyl (or oligo ethylene glycol) terminated thiolates.

Alternatively, covalent bonding to molecules present on the substrate is possible. Reactive polar end groups such as OH, CO₂H and NH₂ are useful in this regard. Alternatively still, an intermediate compound or compounds may be coupled to a desired region of the substrate, and the molecular species coupled to the intermediate compound or compounds. The skilled reader is directed to the wide literature that exists of various techniques for immobilising molecules onto surfaces. In the context of the present invention, what is required is that a monolayer is formed in a desired pattern having an end group which is commensurate with use in a selected immobilisation technique.

A very wide range of devices can be fabricated using the present invention. There are a large number of devices which might incorporate a biological molecule, such as a protein, DNA strand, RNA strand, oligonucleotide or enzyme. Some examples of such devices are described below.

1. Oligonucleotide Arrays.

In one approach, a homofunctional SAM is produced on a substrate, and SNOM used to etch spots, or other desired features, onto the array using the techniques discussed above. A thiolate of contrasting functionality to the originally produced SAM is formed in the spots, such as by immersion in a suitable displacing species. A first base, coupled to a photocleavable protecting group, is attached to the spots formed by the displacing species. Selected spots may be deprotected, and a further base, also with a photocleavable protecting group, is attached. A different sequence may be constructed at each spot by controlling a repeated sequence of deprotection and reaction steps. Such a device offers the potential for building an array capable of hybridising, and hence sequencing, a single DNA molecule.

In a second approach, spots would be produced and a thiolate of a contrasting functionality formed thereon as described in the first approach. Thereafter, pre-synthesised oligonucleotides are attached to the spots. The SNOM might be coupled to a microfluidic delivery system so that rapid stepwise surface functionalisation can be performed.

2. Protein Arrays

Protein arrays can be created in a similar way to the oligonucleotide arrays to discussed above, except that attachment to the spots involves the use of covalent chemistry to attach proteins. The covalent attachment chemistry is well established in the literature. An attraction of coupling the known protein attachment chemistry with the patterning method of the present invention is that it becomes possible to produce nanoscale analogues of processes which are well established at larger scales.

3. Photo-Activated Coupling Agents for Biological Arrays

In this scheme, photocleavable protecting groups are covalently attached to an unpatterned SAM. Treatment by the SNOM results in deprotection of the protecting groups to create ‘active’ features. Molecules such as proteins and oligonucleotides may then bind to the active features. Such a process might be carried out in liquid, holding out the possibility that rapid sequential attachment steps might be performed.

1-24. (Canceled)

25. A method of patterning a monolayer comprising the steps of:
providing a self-assembled monolayer of a compound on a substrate;
positioning a near field light source in relation to the monolayer so that light from the light source irradiates the monolayer in the near field regime, the wavelength of the light being suitable to interact with molecules in the monolayer and thereby initiate a photochemical reaction; and
patterning the monolayer by causing relative movement of the monolayer and the near field light source, the relative movement corresponding to a desired pattern.

26. A method according to claim 25, wherein the near field light source comprises a scanning near field microscope.

27. A method according to claim 25, wherein the molecules in the monolayer which absorb light from the light source are converted by the photochemical reaction into a weakly bound species which is less strongly bound to the substrate than the molecules which originally comprise the monolayer.

28. A method according to claim 27, further comprising displacing the weakly bound species from the substrate with a displacing species.

29. A method according to claim 25, wherein the photochemical reaction is a photooxidation reaction.

30. A method according to claim 25, wherein the molecules in the self-assembled monolayer comprise thiolates.

31. A method according to claim 30, wherein the self-assembled monolayer is formed from thiols.

32. A method according to claim 31, wherein said thiols comprise alkyl thiols.

33. A method according to claim 31, wherein said thiols correspond to the formula HS(CH₂)ₙX, where X is an end group.

34. A method according to claim 33, wherein group X is selected from the group consisting of CH₃, CO₂H and OH.

35. A method according to claim 29, wherein the photooxidation reaction oxidizes a thiolate moiety adsorbed on the substrate to a sulphonate moiety.

36. A method according to claim 28, wherein the displacing species forms a thiolate compound on the substrate.

37. A method according to claim 25, wherein the substrate comprises gold or silver.

38. A method according to claim 25, wherein the light source provides near UV light.

39. A method according to claim 25, wherein the patterning comprises features having at least one dimension in a direction parallel to the substrate which is less than 100 nm.

40. A method according to claim 39, wherein the patterning comprises features having at least one dimension in a direction parallel to the substrate which is less than 50 nm.

41. A method of selectively coupling a molecular species to a surface, comprising the steps of:
patterning a monolayer using a method according to claim 25 to provide at least one feature; and
coupling the molecular species to a compound present on the substrate.

42. A method according to claim 41, wherein the molecular species is coupled to the monolayer.

43. A method according to claim 41, wherein the molecular species is coupled to the at least one feature.

44. A method according to claim 43, wherein in the method used to pattern the monolayer the molecules in the monolayer which absorb light from the light source are converted by the photochemical reaction into a weakly bound species which is less strongly bound to the substrate than the molecules which originally comprise the monolayer; the method used to pattern the monolayer further comprises displacing the weakly bound species from the substrate with a displacing species, and the molecular species is coupled to the displacing species.

45. A method according to claim 41, wherein at least one intermediate compound is coupled to a portion of the patterned monolayer.

46. A method according to claim 41, wherein the coupling comprises adsorption of the molecular species onto the compound.

47. A method according to claim 41, wherein the coupling comprises covalently bonding the molecular species to the compound.

48. A method according to claim 41, wherein the molecular species is a biological molecule.

49. A method according to claim 48, wherein the biological molecule is a protein, a DNA strand, an RNA strand, an oligonucleotide or an enzyme.
